(19) United States
(12) Patent Application Publication
(10) Pub. No.: US 2004/0207024 A1
(43) Pub. Date: Oct. 21, 2004

(54) Semiconductor device with an STI structure which is capable of suppressing inverse narrow channel effect, and method of manufacturing the same

(75) Inventor: Katsumi Eikyu, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 10/748,199

(22) Filed: Dec. 31, 2003

(30) Foreign Application Priority Data
Apr. 21, 2003 (JP) 2003-116003

(51) Int. Cl. H01L 29/76

(52) U.S. Cl. 257/374

(57) ABSTRACT

A trench (10) is formed in an upper portion of a silicon substrate (1), and an isolation insulating film (2) is buried in the trench (10). Each of upper portions of the silicon substrate (1) which are isolated from each other by the isolation insulating film (2) is defined as a region where a MOSFET is to be formed. A thin SiGe layer (4) is formed along a sidewall of the trench (10) in the silicon substrate (1), and a B-containing SiGe layer (5) is formed within the SiGe layer (4) (a portion thereof located closer to the trench (10)).

### BACKGROUND OF THE INVENTION

1. Field of the Invention

The present invention relates to a semiconductor device in which semiconductor elements are isolated from each other by Shallow Trench Isolation (STI), and a method of manufacturing such a semiconductor device.

2. Description of the Background Art

In a MOSFET which is isolated from another element by STI, a threshold voltage of an edge portion of a channel region is likely to be reduced due to loss of impurities in the edge portion of the channel region which is caused by processes of ion implantation and annealing during manufacture, or due to fringing fields by a gate electrode depending on a final configuration of an STI structure formed in carrying out STI. Thus, inverse narrow channel effect is occasionally observed. It is noted that inverse narrow channel effect is a phenomena in which a threshold voltage of an edge portion of a channel region decreases in accordance with decrease of a channel width.

In an attempt to suppress such inverse narrow channel effect, optimization of a final configuration of an STI structure, or optimization of process conditions for ion implantation or annealing, has been accomplished. Alternatively, “sidewall doping” has been proposed. Sidewall doping is carried out as follows. After an isolation trench is formed, a sidewall of an active region (corresponding to a sidewall of the isolation trench) is doped with impurity ions of the same conductivity type as impurities in a channel region, prior to filling the isolation trench with an insulating film, to thereby suppress inverse narrow channel effect. Sidewall doping is taught in Japanese Patent Application Laid-Open No. 10-4137, for example.

Sidewall doping has a drawback, however. While sidewall doping typically employs B (boron) having a high diffusion coefficient as a channel dopant of an N-type MOSFET, to employ B in sidewall doping would result in reduction of concentration of B which is locally contained, due to diffusion of B during a process of isolation or a process of annealing for forming the MOSFET which is to be performed after sidewall doping. This makes it impossible to effectively suppress inverse narrow channel effect. One possible solution to the foregoing problem is use of In (indium) in place of B. However, this solution is not satisfactory because In has a diffusion coefficient roughly equal to a fraction of that of B which is not so sufficiently low, to permit similar problems to occur upon a heat treatment.

### SUMMARY OF THE INVENTION

It is an object of the present invention to obtain a semiconductor device with an STI structure which is capable of effectively suppressing inverse narrow channel effect caused in an insulated gate transistor, and a method of manufacturing such a semiconductor device.

According to a first aspect of the present invention, a semiconductor device includes a semiconductor substrate, a trench, an isolation insulating film, a first semiconductor layer and a second semiconductor layer. The trench is selectively formed, which extends from a surface of the semiconductor substrate to a predetermined depth. The isolation insulating film is buried in the trench. Each of upper portions of the semiconductor substrate which are isolated from each other by the isolation insulating film is defined as a transistor region where a predetermined transistor of an insulated gate type is to be formed. The first semiconductor layer is formed along a side face of the trench in the transistor region. The second semiconductor layer is formed in a portion of the first semiconductor layer which is close to the side face of the trench.

The second semiconductor layer contains a predetermined impurity of the same conductivity type as a channel region of the predetermined transistor. The first semiconductor layer has a property of suppressing diffusion of the predetermined impurity which is caused by a heat treatment.

Diffusion of the predetermined impurity during manufacture can be effectively suppressed, which in turn makes it possible to effectively suppress inverse narrow channel effect in the predetermined transistor.

According to a second aspect of the present invention, a method of manufacturing a semiconductor device includes the following steps (a) through (f). The step (a) is to selectively form a trench extending from a surface of a semiconductor substrate to a predetermined depth. The step (b) is to implant a first impurity toward a side face of the trench in the semiconductor substrate, to form a first impurity implanted region along the side face of the trench in the semiconductor substrate. The step (c) is to implant a second impurity toward the side face of the trench in the semiconductor substrate, to form a second impurity implanted region within the first impurity implanted region. The step (d) is to activate the first and second impurities in the first and second impurity implanted regions by carrying out a heat treatment after the steps (b) and (c), to form a first semiconductor layer and a second semiconductor layer along the side face of the trench in the semiconductor substrate. The step (e) is to form an isolation insulating film in the trench. Each of upper portions of the semiconductor substrate which are isolated from each other by the isolation insulating film is defined as a transistor region where a predetermined transistor of an insulated gate type is to be formed. The step (f) is to form the predetermined transistor in the transistor region.

The second impurity includes an impurity of the same conductivity type as a channel region of the predetermined transistor. The first semiconductor layer has a property of suppressing diffusion of the second impurity.

The second impurity implanted region is formed within the first impurity implanted region by processes in the steps (b) and (c). Then, the heat treatment in the step (d) is carried out with the second impurity implanted region having been formed within the first impurity implanted region. Thus, the first and second semiconductor layers are formed simultaneously.

As such, the second impurity diffuses within the first semiconductor layer having a property of suppressing diffusion of the second impurity. Accordingly, it is possible to effectively suppress diffusion of the second impurity, to thereby obtain a semiconductor device capable of effectively suppressing inverse narrow channel effect in the predetermined transistor.

According to a third aspect of the present invention, a method of manufacturing a semiconductor device includes the following steps (a) through (g). The step (a) is to selectively form a trench extending from a surface of a semiconductor substrate to a predetermined depth. The step (b) is to implant a first impurity toward a side face of the trench in the semiconductor substrate, to form a first impurity implanted region along the side face of the trench in the semiconductor substrate. The step (c) is to activate the first impurity in the first impurity implanted region by carrying out a heat treatment after the step (b), to form a first semiconductor layer along the side face of the trench in the semiconductor substrate. The step (d) is to implant a second impurity toward the side face of the trench in the semiconductor substrate, to form a second impurity implanted region within the first semiconductor layer. The step (e) is to activate the second impurity in the second impurity implanted region by carrying out another heat treatment after the step (d), to form a second semiconductor layer in the first semiconductor layer. The step (f) is to form an isolation insulating film in the trench. Each of upper portions of the semiconductor substrate which are isolated from each other by the isolation insulating film is defined as a transistor region where a predetermined transistor of an insulated gate type is to be formed. The step (g) is to form the predetermined transistor in the transistor region.

The second impurity includes an impurity of the same conductivity type as a channel region of the predetermined transistor. The first semiconductor layer has a property of suppressing diffusion of the second impurity.

The second impurity implanted region is formed within the first impurity implanted region by processes in the steps (b), (c) and (d). Then, the heat treatment for forming the second semiconductor layer is carried out in the step (e) with the second impurity implanted region having been formed within the first impurity implanted region. Thus, the second impurity diffuses within the first semiconductor layer having a property of suppressing diffusion of the second impurity.

Accordingly, it is possible to effectively suppress diffusion of the second impurity, to thereby obtain a semiconductor device capable of effectively suppressing inverse narrow channel effect in the predetermined transistor.

Further, the first semiconductor layer and the second semiconductor layer are formed by the heat treatments carried out independently of each other in the steps (c) and (f), respectively. This allows the heat treatment to be carried out on the first semiconductor layer under conditions suitable to the first semiconductor layer without having to take into account formation of the second semiconductor layer, in the step (c).

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view of a semiconductor device according to a first preferred embodiment of the present invention.

FIG. 2 is a sectional view of a semiconductor device according to a second preferred embodiment of the present invention.

FIGS. 3 through 7 are sectional views for illustrating a method of manufacturing a semiconductor device according to a third preferred embodiment of the present invention.

FIGS. 8 through 12 are sectional views for illustrating a method of manufacturing a semiconductor device according to a fourth preferred embodiment of the present invention.

FIGS. 13 through 16 are sectional views for illustrating a method of manufacturing a semiconductor device according to a fifth preferred embodiment of the present invention.

FIGS. 17 through 21 are sectional views for illustrating a method of manufacturing a semiconductor device according to a sixth preferred embodiment of the present invention.

### DESCRIPTION OF THE PREFERRED EMBODIMENTS

Principles of the Present Invention

According to the present invention, in principle, utilizing a fact that B (or In) is implanted toward only a sidewall of a trench (i.e., a portion of a substrate surrounding the trench) in sidewall doping, a layer in which diffusion of B is suppressed (hereinafter, referred to as a “B-diffusion suppression layer”) is selectively formed only along the sidewall of the trench and B is implanted into the B-diffusion suppression layer, to suppress diffusion of B without adversely affecting a MOSFET isolated from another element by STI.

For a B-diffusion suppression layer, an SiGe (silicon germanium) layer can be employed in view of its basic physical properties. It has been reported in the study of basic physical properties that a diffusion coefficient of an impurity having the same diffusing property as an interstitial atom such as Si, decreases as a concentration of Ge increases in SiGe.

Further, the inventor of the present invention has observed that formation of a thin SiGe layer along a sidewall of a trench does not adversely affect performance of a MOSFET.

First Preferred Embodiment

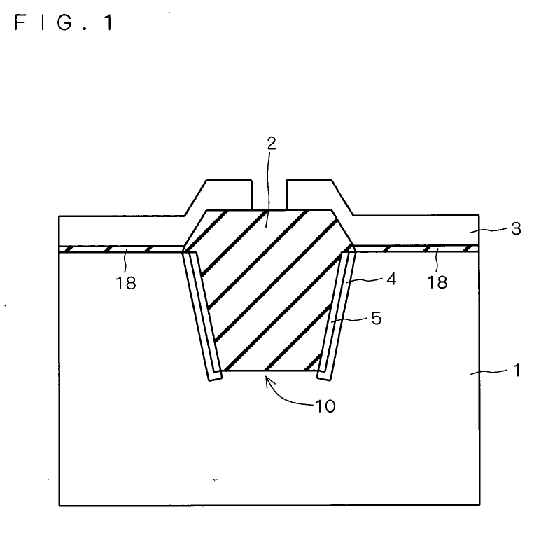

FIG. 1 is a sectional view of a semiconductor device according to a first preferred embodiment of the present invention. As illustrated in FIG. 1, a trench 10 is formed in an upper portion of a silicon substrate 1 serving as a semiconductor substrate, and an isolation insulating film 2 is buried in the trench 10. The isolation insulating film 2 defines a region where a MOSFET (transistor) is to be formed (hereinafter, referred to as a “MOSFET (transistor) region”) in the upper portion of the silicon substrate 1.

A gate oxide film 18 is formed on a surface of a portion of the silicon substrate 1 which portion does not include the trench 10. Also, a gate electrode layer 3 made of polysilicon or the like is formed on the gate oxide film 18. It is noted that FIG. 1 is a sectional view of a portion of an N-type MOSFET where a channel region is provided, taken along a channel width. As such, source/drain regions are to be formed in an orthogonal direction relative to a sheet of FIG. 1.

Further, a thin SiGe layer 4 serving as a first semiconductor layer is formed along a sidewall (side face) of the trench 10 in the silicon substrate 1. Moreover, an SiGe layer containing B (hereinafter, referred to as a “B-containing SiGe layer”) 5 serving as a second semiconductor layer is formed within the SiGe layer 4 (a portion thereof closer to the trench 10). Accordingly, the SiGe layer 4 and the B-containing SiGe layer 5 in the upper portion of the silicon substrate 1 are placed in an edge portion of the channel region of the MOSEFT.

A thickness of the SiGe layer 4 is controlled so as to effectively suppress diffusion of B without adversely affecting performance of the MOSFET to be formed while being isolated from another element by the trench 10. For example, if a distance between the trench 10 and another trench 10 adjacent to each other (it is noted that though only one trench is illustrated as the trench 10 in FIG. 1, a plurality of trenches each as the trench 10 are actually provided) is 100 nm, it is preferable that the thickness of the SiGe layer 4 is approximately 20 nm or smaller. By controlling the thickness of the SiGe layer 4 in the foregoing manner, it is possible to prevent performance of the MOSFET from being adversely affected.

Also, it is preferable that the SiGe layer 4 (the B-containing SiGe layer 5) contains 1 at % (atomic percent, “at” is atomicity) or more Ge for the reasons that an effect of suppressing diffusion of B is not produced unless Ge has a concentration of the order of several at % in the SiGe layer 4.

On the other hand, it is preferable to control a concentration of B in the B-containing SiGe layer 5 so as to allow for local compensation of channel dopants and not to exceed 4×10¹⁸ cm⁻³ (if the concentration of B exceeds 4×10¹⁸ cm⁻³, interband tunneling at a pn junction becomes so prominent that leakage current increases significantly). Also, a thickness of the B-containing SiGe layer 5 should be controlled so as to prevent the B-containing SiGe layer 5 from expanding over the isolation insulating film 2 during an oxidation process to be later carried out. Specifically, it is preferable that the B-containing SiGe layer 5 is formed such that a portion thereof located in a corner of the channel region has a thickness of several tens of nanometers or smaller. Further, it is preferable that the thickness of the SiGe layer 4 is optimized to surely accommodate the B-containing SiGe layer 5, taking into account the thickness of B-containing SiGe layer 5.

As described above, the semiconductor device according to the first preferred embodiment includes the B-containing SiGe layer 5 which is formed within the SiGe layer 4 functioning as a B-diffusion suppression layer. Accordingly, diffusion of B from the B-containing SiGe layer 5 is prevented by presence of SiGe in each of the SiGe layer 4 and the B-containing SiGe layer 5 during a heat treatment to be performed after formation of the B-containing SiGe layer 5. Hence, it is possible to maintain the concentration of B locally contained, at a level which allows for suppression of inverse narrow channel effect.

As a result, the semiconductor device according to the first preferred embodiment produces an effect of effectively suppressing inverse narrow channel effect without adversely affecting performance of a MOSFET isolated from another element by STI.

Second Preferred Embodiment

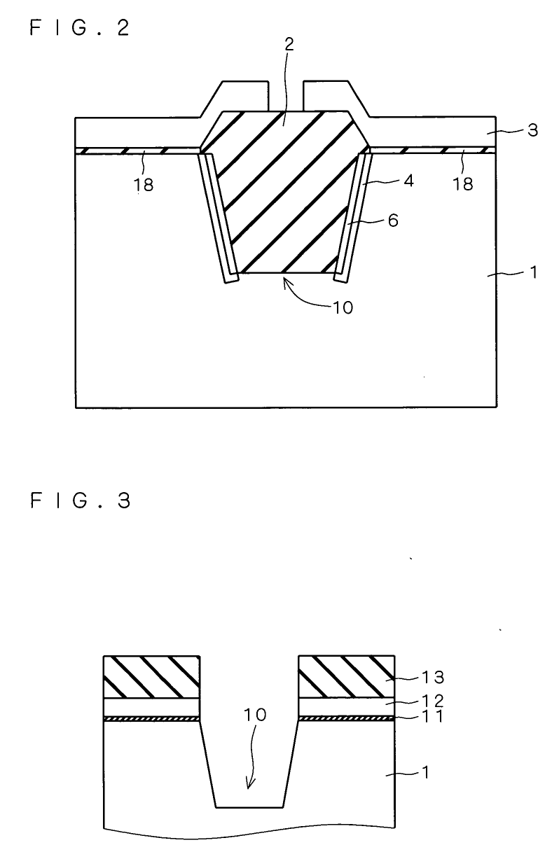

FIG. 2 is a sectional view of a semiconductor device according to a second preferred embodiment of the present invention. As illustrated in FIG. 2, the thin SiGe layer 4 is formed along a sidewall of the trench 10 in the same manner as in the first preferred embodiment. According to the second preferred embodiment, an SiGe layer containing In (hereinafter, referred to as an “In-containing SiGe layer”) 6 is formed within the SiGe layer 4 (a portion thereof closer to the trench 10).

It is preferable to control a concentration of In in the In-containing SiGe layer 6 so as to allow for local compensation of channel dopants and not to exceed 4×10¹⁸ cm⁻³. Also, a thickness of the In-containing SiGe layer 6 should be controlled so as to prevent the In-containing SiGe layer 6 from expanding over the isolation insulating film 2 during an oxidation process to be later carried out. Specifically, it is preferable that the In-containing SiGe layer 6 is formed such that a portion thereof located in a corner of the channel region has a thickness of several tens of nanometers or smaller. Further, it is preferable that the thickness of the SiGe layer 4 is optimized to surely accommodate the In-containing SiGe layer 6, taking into account the thickness of the In-containing SiGe layer 6.

Moreover, the gate oxide film 18 is formed on a surface of a portion of the silicon substrate 1 which portion does not include the trench 10, and the gate electrode layer 3 is formed on the gate oxide film 18, in the same manner as in the first preferred embodiment.

As described above, the semiconductor device according to the second preferred embodiment includes the In-containing SiGe layer 6 which is formed within the SiGe layer 4 functioning as an In-diffusion suppression layer in which diffusion of In is suppressed. Accordingly, diffusion of In from the In-containing SiGe layer 6 is prevented by presence of SiGe in each of the SiGe layer 4 and the In-containing SiGe layer 6 during a heat treatment to be carried out after formation of the In-containing SiGe layer 6. As a result, the semiconductor device according to the second preferred embodiment produces the effect of effectively suppressing inverse narrow channel effect without adversely affecting performance of a MOSFET, in the same manner as the semiconductor device according to the first preferred embodiment.

Further, the semiconductor device according to the second preferred embodiment produces an additional effect of decreasing the thickness of the SiGe layer 4 as compared to that in the semiconductor device according to the first preferred embodiment, because In has a diffusion coefficient lower than that of B.

Third Preferred Embodiment

FIGS. 3 through 7 are sectional views for illustrating a method of manufacturing a semiconductor device according to a third preferred embodiment of the present invention. The method of manufacturing a semiconductor device according to the third preferred embodiment is one of methods (a first method) suitably applied to manufacture of the semiconductor device according to the first preferred embodiment.

First, mask layers 11, 12 and 13 are sequentially formed on a surface of the silicon substrate 1, and then are patterned. Subsequently, an etching process is carried out on the silicon substrate 1 from the surface thereof using the mask layers 11, 12 and 13 collectively as a mask, to selectively form the trench 10 in an upper portion of the silicon substrate 1, as illustrated in FIG. 3. Additionally, for the mask layers 11, 12 and 13, a trilayer structure of an oxide film, a polysilicon layer and a nitride film can be employed, for example. Also, a bilayer structure of an oxide film and a nitride film can be alternatively employed for the mask layers 11, 12 and 13.

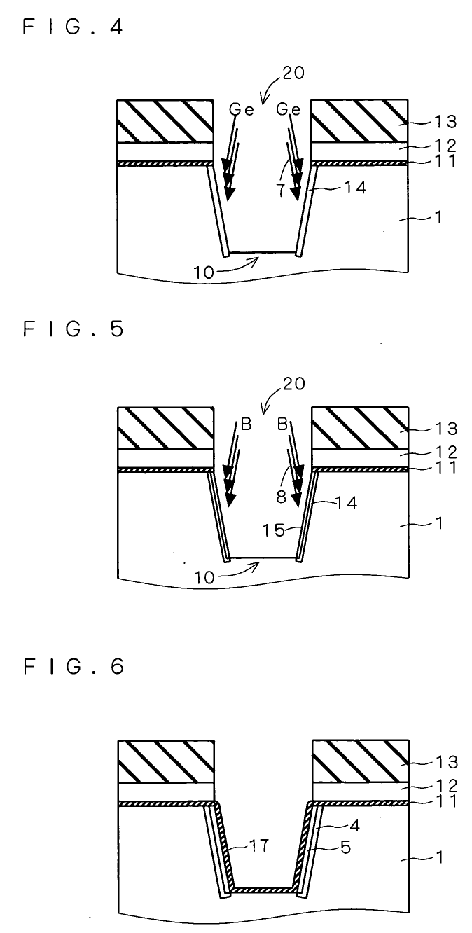

Next, a Ge ion 7 is implanted at a tilt angle from an opening 20 formed in the mask layers 11, 12 and 13 toward a sidewall of the trench 10 as illustrated in FIG. 4. Then, a Ge implanted region 14 is formed along the sidewall of the trench 10, as a first impurity implanted region. It is noted that Ge will be treated as a first impurity to be implanted into the silicon substrate 1 in the present specification.

Subsequently, a B ion 8 is implanted at a tilt angle from the opening 20 formed in the mask layers 11, 12 and 13 toward the sidewall of the trench 10 as illustrated in FIG. 5. Then, a B implanted region 15 is formed as a second impurity implanted region. At that time, the B implanted region 15 is formed within the Ge implanted region 14. It is noted that B will be treated as a second impurity to be implanted into the silicon substrate 1, which is of the same conductivity type as the channel region of the N-type MOSFET.

Thereafter, a heat treatment is carried out in an atmosphere of oxygen, to activate Ge and B contained in the Ge and B implanted regions 14 and 15, to thereby form the SiGe layer 4 and the B-containing SiGe layer 5 accommodated in the SiGe layer 4 as illustrated in FIG. 6. At that time, a thin film of thermal oxide (thermal oxide film) 17 is also formed on an inner wall of the trench 10. The formation of the thermal oxide film 17 serves to round an upper corner of the trench 10, which provides for reduction of electric field concentration on the upper corner of the trench 10 when electric field is applied from a gate electrode after formation of the MOSFET. Additionally, the heat treatment can alternatively be carried out in an atmosphere of any other type than noted above (an atmosphere of oxygen) such as an atmosphere of nitrogen.

Then, an insulating film is buried in the trench 10 using the mask layers 11, 12 and 13 collectively as a mask, and a CMP process is carried out, to form the isolation insulating film 2 (which is formed to be integral with the thermal oxide film 17), as illustrated in FIG. 7. Each of upper portions of the silicon substrate 1 which are isolated from each other by the isolation insulating film 2 is defined as a MOSFET region.

The mask layers 11, 12 and 13 are removed, and a P-well region (which can be omitted if the silicon substrate 1 is of P-type), the gate oxide film 18, the gate electrode layer 3 (see FIG. 1); source/drain regions and the like are formed in the MOSFET region to form a MOSFET by the conventional method, to thereby complete the semiconductor device according to the first preferred embodiment illustrated in FIG. 1 (the isolation insulating film 2 has a shape illustrated in FIG. 1 as a result of removal of an upper portion thereof during a wet etching process in manufacture of the MOSFET). It is noted that respective processes included in the manufacturing method according to the third preferred embodiment are carried out so as to satisfy requirements set forth in the first preferred embodiment, regarding the thickness and the concentration of Ge of the SiGe layer 4, the thickness and the concentration of B of the B-containing SiGe layer 5, and the like.

As described above, according to the manufacturing method of the third preferred embodiment, the SiGe layer 4 and the B-containing SiGe layer 5 are simultaneously formed by one heat treatment illustrated in FIG. 6. Accordingly, B in the B implanted region 15 diffuses within SiGe, in which case a diffusion coefficient of B is reduced. As a result, it is possible to obtain the semiconductor device according to the first preferred embodiment which includes the B-containing SiGe layer 5 while effectively suppressing diffusion of B locally introduced during the process of ion implantation of the B ion 8 illustrated in FIG. 5.

Further, by implanting the Ge ion 7 during the process of ion implantation illustrated in FIG. 4 at a high dose (a dose which allows the Ge implanted region 14 to contain 1 at % Ge for reducing a diffusion coefficient of B will be sufficient) in the manufacturing method according to the third preferred embodiment, it is possible to make the sidewall of the trench 10 amorphous, to thereby suppress channeling which is likely to occur during the process of implantation of the B ion 8.

Moreover, by controlling a tilt angle in the process of implantation of the Ge ion 7 or the B ion 8 such that a bottom portion of the trench 10 can be appropriately shaded by the mask layers 11, 12 and 13, it is possible to either prevent Ge/B from being introduced into the bottom portion of the trench 10, or permitting Ge/B to be introduced into the bottom portion of the trench 10. Additionally, it is irrelevant whether or not Ge/B is introduced into the bottom portion of the trench 10 in the third preferred embodiment.

Fourth Preferred Embodiment

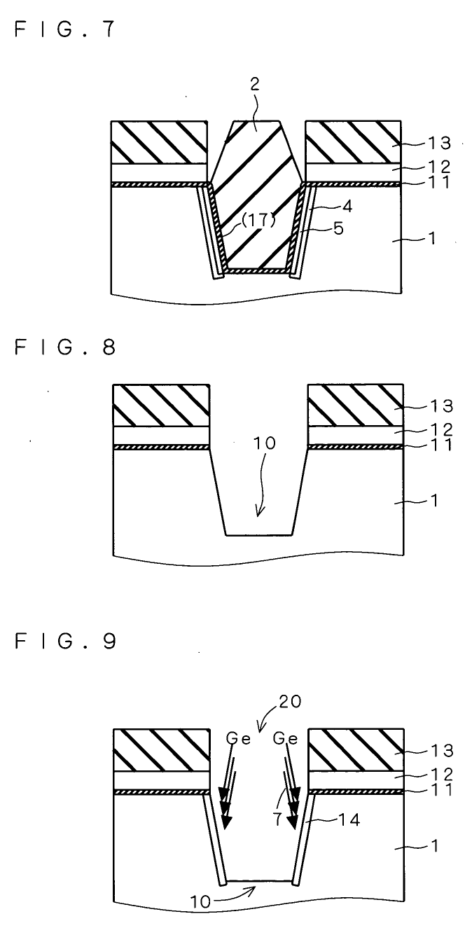

FIGS. 8 through 12 are sectional views for illustrating a method of manufacturing a semiconductor device according to a fourth preferred embodiment of the present invention. The method of manufacturing a semiconductor device according to the fourth preferred embodiment is a second method of manufacturing the semiconductor device according to the first preferred embodiment.

First, the mask layers 11, 12 and 13 are sequentially formed on a surface of the silicon substrate 1, and then are patterned. Subsequently, an etching process is carried out on the silicon substrate 1 from the surface thereof using the mask layers 11, 12 and 13 collectively as a mask, to selectively form the trench 10 in an upper portion of the silicon substrate as illustrated in FIG. 8.

Next, the Ge ion 7 is implanted at a tilt angle from the opening 20 formed in the mask layers 11, 12 and 13 toward a sidewall of the trench 10 in the silicon substrate 1 as illustrated in FIG. 9. Then, the Ge implanted region 14 is formed along the sidewall of the trench 10.

Thereafter, a heat treatment is carried out in an atmosphere of oxygen, to activate Ge contained in the Ge implanted region 14, to thereby form the SiGe layer 4 as illustrated in FIG. 10. At that time, the thin thermal oxide film 17 is also formed on an inner wall of the trench 10. Additionally, the heat treatment can alternatively be carried out in an atmosphere of any other type than noted above (an atmosphere of oxygen) such as an atmosphere of nitrogen.

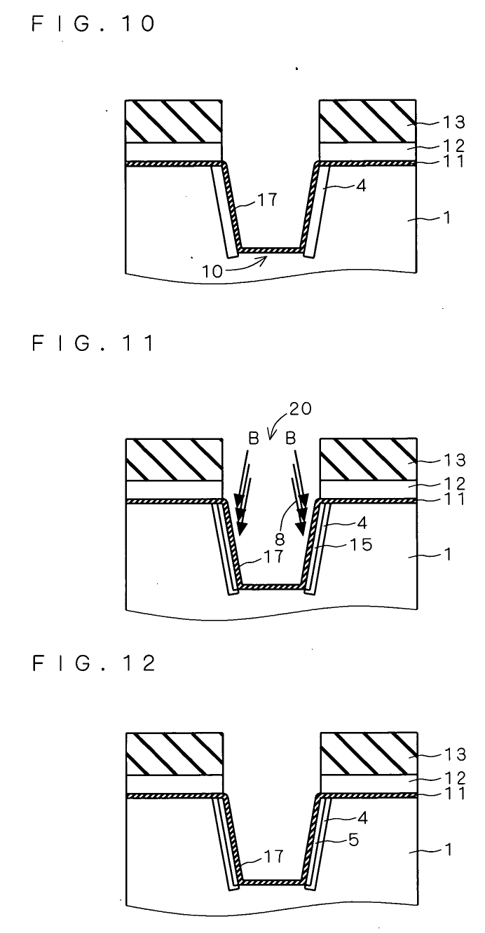

Subsequently, the B ion 8 is implanted at a tilt angle from the opening 20 formed in the mask layers 11, 12 and 13 into a surface portion of the SiGe layer 4 along the sidewall of the trench 10 as illustrated in FIG. 11. Then, the B implanted region 15 is formed within the SiGe layer 4.

Then, a heat treatment is carried out in an atmosphere of oxygen, to activate B contained in the B implanted region 15 within the SiGe layer 4, to thereby form the B-containing SiGe layer 5, as illustrated in FIG. 12. At that time, as B diffuses within SiGe so that a diffusion coefficient thereof is kept low, the B-containing SiGe layer 5 is formed within the SiGe layer 4. Additionally, the heat treatment can alternatively carried out in an atmosphere of any other type than noted above (an atmosphere of oxygen) such as an atmosphere of nitrogen.

Following this, after the isolation insulating film 2 is formed in the trench 10, a MOSFET is formed by the conventional method in the same manner as in the third preferred embodiment, to thereby complete the semiconductor device according to the first preferred embodiment illustrated in FIG. 1. It is noted that respective processes in the manufacturing method according to the fourth preferred embodiment are carried out so as to satisfy requirements set forth in the first preferred embodiment, regarding the thickness and the concentration of Ge of the SiGe layer 4, the thickness and the concentration of B of the B-containing SiGe layer 5, and the like.

As described above, according to the manufacturing method of the fourth preferred embodiment, the SiGe layer 4 and the B-containing SiGe layer 5 are formed independently of each other by the heat treatments illustrated in FIGS. 10 and 12, respectively. During the heat treatment illustrated in FIG. 12, B diffuses within SiGe, in which case a diffusion coefficient of B is reduced. As a result, it is possible to obtain the semiconductor device according to the first preferred embodiment which effectively suppresses diffusion of B locally introduced during the process of implantation of the B ion 8 illustrated in FIG. 11.

Also, in the manufacturing method according to the fourth preferred embodiment, as the SiGe layer 4 and the B-containing SiGe layer 5 are formed by distinct processes, the SiGe layer 4 can be formed by a heat treatment under conditions suitable to formation of the SiGe layer 4 without the need of taking into account formation of the B-containing SiGe layer 5.

Further, as the heat treatment for forming the SiGe layer 4 is carried out prior to implantation of the B ion 8, a crystal defect possibly created in the sidewall of the trench 10 due to implantation of the Ge ion 7 can be thoroughly remedied before implantation of the B ion 8. Thus, influences exerted on diffusion of B by a possible crystal defect can be reduced.

More specifically, in the manufacturing method according to the third preferred embodiment, crystallization of SiGe and diffusion of B occur simultaneously. In such a case, TED (Transient Enhanced Diffusion) of B may be caused due to a crystal defect created due to implantation of Ge, so that diffusion of B may not be satisfactorily suppressed. In contrast thereto, in the manufacturing method according to the fourth preferred embodiment, a possible crystal defect is remedied before diffusion of B as noted above. Thus, it is possible to surely avoid TED of B.

Moreover, by controlling a tilt angle in the process of implantation of the Ge ion 7 or the B ion 8 such that a bottom portion of the trench 10 can be appropriately shaded by the mask layers 11, 12 and 13, it is possible to either prevent Ge/B from being introduced into the bottom portion of the trench 10, or permitting Ge/B to be introduced into the bottom portion of the trench 10. Additionally, it is irrelevant whether or not Ge/B is introduced into the bottom portion of the trench 10 in the fourth preferred embodiment.

Fifth Preferred Embodiment

FIGS. 13 through 16 are sectional views for illustrating a method of manufacturing a semiconductor device according to a fifth preferred embodiment of the present invention. The method of manufacturing a semiconductor device according to the fifth preferred embodiment is one of methods (first method) suitably applied to manufacture of the semiconductor device according to the second preferred embodiment.

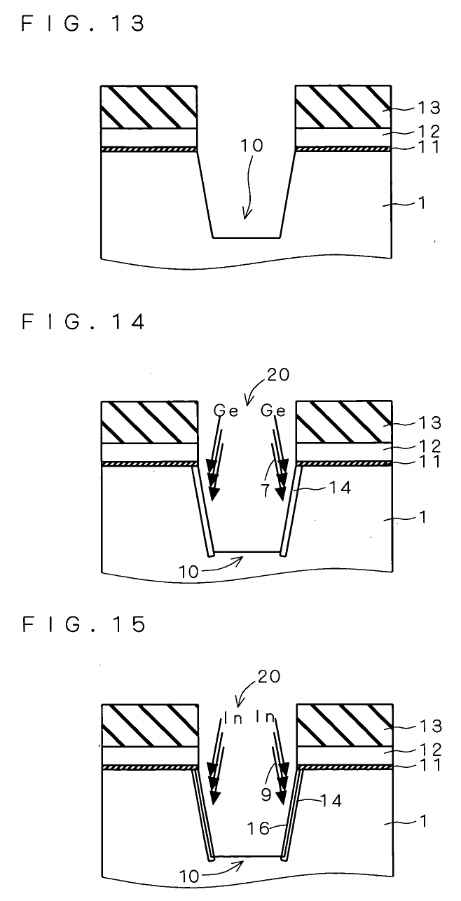

First, the trench 10 and the Ge implanted region 14 are formed as illustrated in FIGS. 13 and 14, in the same manner as illustrated in FIGS. 3 and 4 and described in the third preferred embodiment.

Subsequently, an In ion 9 is implanted at a tilt angle from the opening 20 formed in the mask layers 11, 12 and 13 toward a sidewall of the trench 10 as illustrated in FIG. 15. Then, an In implanted region 16 is formed as another second impurity implanted region. At that time, the In implanted region 16 is formed within the Ge implanted region 14.

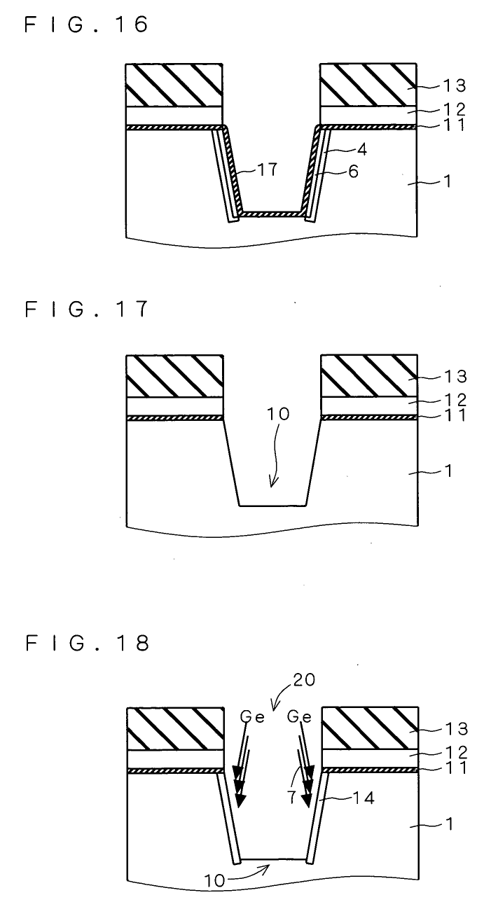

Thereafter, a heat treatment is carried out, to form the SiGe layer 4 and the In-containing SiGe layer 6 accommodated in the SiGe layer 4 as illustrated in FIG. 16. At that time, the thin thermal oxide film 17 is also formed on an inner wall of the trench 10.

Following this, the isolation insulating film 2 is formed in the trench 10 and a MOSFET is formed by the conventional method in the same manner as in the third preferred embodiment, to thereby complete the semiconductor device according to the second preferred embodiment illustrated in FIG. 2. It is noted that respective processes in the manufacturing method according to the fifth preferred embodiment are carried out so as to satisfy requirements set forth in the second preferred embodiment, regarding the thickness and the concentration of Ge of the SiGe layer 4, the thickness and the concentration of In of the In-containing SiGe layer 6, and the like.

As described above, according to the manufacturing method of the fifth preferred embodiment, the SiGe layer 4 and the In-containing SiGe layer 6 are simultaneously formed by one heat treatment as illustrated in FIG. 16. Accordingly, In in the In implanted region 16 diffuses within SiGe, in which case a diffusion coefficient of In is reduced. As a result, it is possible to obtain the semiconductor device according to the second preferred embodiment which includes the In-containing SiGe layer 6 while effectively suppressing diffusion of In locally introduced during the process of ion implantation of the In ion 9 illustrated in FIG. 15.

Further, by implanting the Ge ion 7 during the process of ion implantation illustrated in FIG. 14 at a high dose in the manufacturing method according to the fifth preferred embodiment, it is possible to make the sidewall of the trench 10 amorphous, to thereby suppress channeling which is likely to occur during the process of implantation of the In ion 9.

Moreover, by controlling a tilt angle in the process of implantation of the Ge ion 7 or the In ion 9 such that a bottom portion of the trench 10 can be appropriately shaded by the mask layers 11, 12 and 13, it is possible to either prevent Ge/In from being introduced into the bottom portion of the trench 10, or permitting Ge/In to be introduced into the bottom portion of the trench 10. Additionally, it is irrelevant whether or not Ge/In is introduced into the bottom portion of the trench 10 in the fifth preferred embodiment.

Sixth Preferred Embodiment

FIGS. 17 through 21 are sectional views for illustrating a method of manufacturing a semiconductor device according to a sixth preferred embodiment of the present invention. The method of manufacturing a semiconductor device according to the sixth preferred embodiment is a second method of manufacturing the semiconductor device according to the second preferred embodiment.

First, the trench 10, the Ge implanted region 14 (which will become the SiGe layer 4 by the step illustrated in FIG. 10), the SiGe layer 4 and the gate oxide film 18 are sequentially formed as illustrated in FIGS. 17, 18 and 19, in the same manner as illustrated in FIGS. 8, 9 and 10 and described in the fourth preferred embodiment.

Subsequently, the In ion 9 is implanted at a tilt angle from the opening 20 formed in the mask layers 11, 12 and 13 into a surface portion of the SiGe layer 4 along the sidewall of the trench 10 as illustrated in FIG. 20. Then, the In implanted region 16 is formed within the SiGe layer 4.

Then, a heat treatment is carried out, to activate In contained in the In implanted region 16 within the SiGe layer 4, to thereby form the In-containing SiGe layer 6, as illustrated in FIG. 21. At that time, as In diffuses within SiGe so that a diffusion coefficient thereof is kept low, the In-containing SiGe layer 6 is formed within the SiGe layer 4.

Following this, after the isolation insulating film 2 is formed in the trench 10, a MOSFET is formed by the conventional method in the same manner as in the third preferred embodiment, to thereby complete the semiconductor device according to the second preferred embodiment illustrated in FIG. 2. It is noted that respective processes in the manufacturing method according to the sixth preferred embodiment are carried out so as to satisfy requirements set forth in the second preferred embodiment, regarding the thickness and the concentration of Ge of the SiGe layer 4, the thickness and the concentration of In of the In-containing SiGe layer 6, and the like.

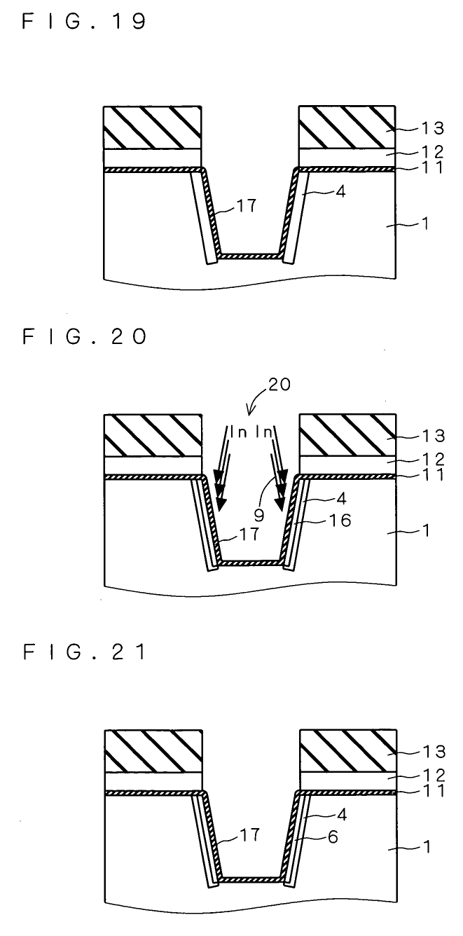

As described above, according to the manufacturing method of the sixth preferred embodiment, the SiGe layer 4 and the In-containing SiGe layer 6 are formed independently of each other by the heat treatments illustrated in FIGS. 19 and 21, respectively. During the heat treatment illustrated in FIG. 21, In diffuses within SiGe, in which case a diffusion coefficient of In is reduced. As a result, it is possible to obtain the semiconductor device according to the second preferred embodiment which effectively suppresses diffusion of In locally introduced during the process of implantation of the In ion 9 illustrated in FIG. 20.

Also, in the manufacturing method according to the sixth preferred embodiment, as the SiGe layer 4 and the In-containing SiGe layer 6 are formed by distinct processes, the SiGe layer 4 can be formed by a heat treatment under conditions suitable to formation of the SiGe layer 4.

Further, as the heat treatment for forming the SiGe layer 4 is carried out prior to implantation of the In ion 9, a crystal defect possibly created in the sidewall of the trench 10 due to implantation of the Ge ion 7 can be thoroughly remedied before implantation of the In ion 9. Thus, influences exerted on diffusion of In by a possible crystal defect can be reduced.

More specifically, in the manufacturing method according to the fifth preferred embodiment, crystallization of SiGe and diffusion of In occur simultaneously. In such a case, TED of In may be caused due to a crystal defect created due to implantation of Ge, so that diffusion of In may not be satisfactorily suppressed. In contrast thereto, in the manufacturing method according to the sixth preferred embodiment, a possible crystal defect is remedied before diffusion of In as noted above. Thus, it is possible to surely avoid TED of In.

Moreover, by controlling a tilt angle in the process of implantation of the Ge ion 7 or the In ion 9 such that a bottom portion of the trench 10 can be appropriately shaded by the mask layers 11, 12 and 13, it is possible to either prevent Ge/In from being introduced into the bottom portion of the trench 10, or permitting Ge/In to be introduced into the bottom portion of the trench 10. Additionally, it is irrelevant whether or not Ge/In is introduced into the bottom portion of the trench 10 in the sixth preferred embodiment.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a semiconductor substrate;
a trench selectively formed which extends from a surface of said semiconductor substrate to a predetermined depth;
an isolation insulating film buried in said trench, each of upper portions of said semiconductor substrate which are isolated from each other by said isolation insulating film being defined as a transistor region where a predetermined transistor of an insulated gate type is to be formed;
a first semiconductor layer formed along a side face of said trench in said transistor region; and
a second semiconductor layer formed in a portion of said first semiconductor layer which is close to said side face of said trench, wherein
said second semiconductor layer contains a predetermined impurity of the same conductivity type as a channel region of said predetermined transistor, and
said first semiconductor layer has a property of suppressing diffusion of said predetermined impurity which is caused by a heat treatment.

2. The semiconductor device according to claim 1, wherein
said first semiconductor layer includes an SiGe layer,
said predetermined impurity includes B (boron), and
said second semiconductor layer includes a B-containing SiGe layer which is an SiGe layer containing B.

3. The semiconductor device according to claim 1, wherein
said first semiconductor layer includes an SiGe layer,
said predetermined impurity includes In (indium), and
said second semiconductor layer includes an In-containing SiGe layer which is an SiGe layer containing In.

4. A method of manufacturing a semiconductor device comprising the steps of:
(a) selectively forming a trench extending from a surface of a semiconductor substrate to a predetermined depth;
(b) implanting a first impurity toward a side face of said trench in said semiconductor substrate, to form a first impurity implanted region along said side face of said trench in said semiconductor substrate;
(c) implanting a second impurity toward said side face of said trench in said semiconductor substrate, to form a second impurity implanted region within said first impurity implanted region;
(d) activating said first and second impurities in said first and second impurity implanted regions by carrying out a heat treatment after said steps (b) and (c), to form a first semiconductor layer and a second semiconductor layer along said side face of said trench in said semiconductor substrate;
(e) forming an isolation insulating film in said trench, each of upper portions of said semiconductor substrate which are isolated from each other by said isolation insulating film being defined as a transistor region where a predetermined transistor of an insulated gate type is to be formed; and
(f) forming said predetermined transistor in said transistor region, wherein
said second impurity includes an impurity of the same conductivity type as a channel region of said predetermined transistor, and
said first semiconductor layer has a property of suppressing diffusion of said second impurity.

5. A method of manufacturing a semiconductor device comprising the steps of:
(a) selectively forming a trench extending from a surface of a semiconductor substrate to a predetermined depth;
(b) implanting a first impurity toward a side face of said trench in said semiconductor substrate, to form a first impurity implanted region along said side face of said trench in said semiconductor substrate;
(c) activating said first impurity in said first impurity implanted region by carrying out a heat treatment after said step (b), to form a first semiconductor layer along said side face of said trench in said semiconductor substrate;
(d) implanting a second impurity toward said side face of said trench in said semiconductor substrate, to form a second impurity implanted region within said first semiconductor layer;
(e) activating said second impurity in said second impurity implanted region by carrying out another heat treatment after said step (d), to form a second semiconductor layer in said first semiconductor layer;
(f) forming an isolation insulating film in said trench, each of upper portions of said semiconductor substrate which are isolated from each other by said isolation insulating film being defined as a transistor region where a predetermined transistor of an insulated gate type is to be formed; and
(g) forming said predetermined transistor in said transistor region, wherein
said second impurity includes an impurity of the same conductivity type as a channel region of said predetermined transistor, and
said first semiconductor layer has a property of suppressing diffusion of said second impurity.

6. The method of manufacturing a semiconductor device according to claim 4, wherein
said semiconductor substrate includes a silicon substrate,
said first impurity includes Ge (germanium),
said second impurity includes B (boron),
said first semiconductor layer includes an SiGe layer, and
said second semiconductor layer includes a B-containing SiGe layer which is an SiGe layer containing B.

7. The method of manufacturing a semiconductor device according to claim 4, wherein
said semiconductor substrate includes a silicon substrate,
said first impurity includes Ge (germanium),
said second impurity includes In (indium),
said first semiconductor layer includes an SiGe layer, and
said second semiconductor layer includes an In-containing SiGe layer which is an SiGe layer containing In.

8. The method of manufacturing a semiconductor device according to claim 5, wherein
said semiconductor substrate includes a silicon substrate,
said first impurity includes Ge (germanium),
said second impurity includes B (boron),
said first semiconductor layer includes an SiGe layer, and
said second semiconductor layer includes a B-containing SiGe layer which is an SiGe layer containing B.

9. The method of manufacturing a semiconductor device according to claim 5, wherein
said semiconductor substrate includes a silicon substrate,
said first impurity includes Ge (germanium),
said second impurity includes In (indium),
said first semiconductor layer includes an SiGe layer, and
said second semiconductor layer includes an In-containing SiGe layer which is an SiGe layer containing In.
